(19) United States
(12) Patent Application Publication
(10) Pub. No.: US 2026/0327807 A1
(43) Pub. Date: Oct. 22, 2026

(54) HARD COATING FILM FOR CUTTING TOOL

(71) Applicant: KORLOY INC., Seoul (KR)

(72) Inventors: Jin Han GWON, Cheongju-si, Chungcheongbuk-do (KR); Seung Su AHN, Cheongju-si, Chungcheongbuk-do (KR); Je Hun PARK, Cheongju-si, Chungcheongbuk-do (KR); Yeong Ju JO, Cheongju-si, Chungcheongbuk-do (KR); Hyung Jin KIM, Cheongju-si, Chungcheongbuk-do (KR)

(21) Appl. No.: 18/881,019

(22) PCT Filed: Jun. 28, 2023
(86) PCT No.: PCT/KR2023/009072

§ 371 Date: Jan. 3, 2025

(30) Foreign Application Priority Data
Sep. 29, 2022 (KR) 10-2022-0124668

(51) Int. Cl. C23C 30/00; B23C 5/16

(52) U.S. Cl. CPC C23C 30/005; B23C 5/16; B23C 2228/10

(57) ABSTRACT

A cutting tool for a hard coating film includes a hard coating film, in which: a first macroscopic roughness (macro_S_{aR1}, which is a macroscopic surface roughness when the surface roughness of the hard coating film is measured within 100 μm in the direction of the rake surface from the cutting edge of the hard coating film, may be less than a second macroscopic roughness); and a third macroscopic roughness (macro_S_{aF1}, which is a macroscopic surface roughness when the surface roughness is measured within 100 μm from the cutting edge in the direction of the flank surface, may be less than a fourth macroscopic roughness).

### TECHNICAL FIELD

The present invention relates to a hard coating film for a cutting tool, and more particularly, to a hard coating film having difference roughness in an inner range and an outer range centered on a predetermine distance from a cutting edge of the hard coating film.

### BACKGROUND ART

In order to improve cutting performance and extend the lifespan of cutting tolls when processing high-hardness material to be cut, which has a hardness of 50 or more according to the HRC standard such as high-hardness steel, and a material that is difficult to be cut, which causes severe adhesion and chipping, a technology of a hard coating film made of various ceramics on a hard base material such as cemented carbide, cermet, end mill, or drill is being adopted.

The hard coating film formed through deposition technologies on the hard base material has a risk of peeling by increasing stress of the hard coating film due to a difference in lattice constant between the hard base material and the hard coating film and characteristics of a physical vapor deposition method. To solve this problem, the adhesion of the hard coating film has been improved through pre-treatment, etching, an adhesion layer, a thin film having a multi-layered structure, and a post-processing technology.

When applying processes such as the pre-treatment and the etching, a specific surface area of a surface of the hard base material may increase to improve the adhesion between the base material and the thin film. However, depending on the material to be cut, especially in stainless steel and inconel cutting, the increasing of the specific surface area may lead to increase in weldability between the thin film and the material to be cut, thereby deteriorating the lifespan of the tool due to tearing of the hard coating film.

To solve this problem, in the related art, a post-treatment process of the hard coating film has been applied to reduce surface roughness of the tool, thereby improving lubricity. However, in spite of these efforts, there are limits to improve the roughness through the post-treatment process of the hard coating film, and there are disadvantages in terms of manufacturing efficiency due to an additional process. In addition, even in processing situations in the hard base material state after the hard coating film is peeled, the problem of the reduction in lifespan of the tool occurs by the increasing weldability due to the still high specific surface area of the hard base material, and thus, it is necessary to solve the problem. However, if the specific surface area of the hard base material is excessively reduced, the adhesion between the hard base material and the hard coating film may decrease to accelerate the peeling of the film.

### DISCLOSURE OF THE INVENTION

### Technical Problem

An object of the present invention is to provide a cutting tool for a hard coating film having excellent welding resistance and wear resistance.

### Technical Solution

In order to achieve the above objective, a cutting tool provided by the present invention includes a hard coating film, wherein, in the hard coating film, first macroscopic roughness (macro_S_{aR1}), which is macroscopic surface roughness when measuring surface roughness within a range of 100 μm from a cutting edge of the hard coating film in a direction of a rake surface, is less than second macroscopic roughness (macro_S_{aR2}), which is macroscopic surface roughness when measuring surface roughness outside of 100 μm from the edge in the direction of the rake surface, first microscopic roughness (micro_S_{aR1}), which is a microscopic surface roughness when measuring surface roughness within a range of 100 μm from the cutting edge in the direction of the rake surface, is less than second micro-roughness (micro_S_{aR2}), which is microscopic surface roughness when measuring surface roughness out of 100 μm from the cutting edge in the direction of the rake surface, third macroscopic roughness (macro_S_{aF1}), which is macroscopic surface roughness when measuring surface roughness within 100 μm from the cutting edge in the direction of the flank surface, is less than fourth macroscopic roughness (macro_S_{aF2}), which is macroscopic surface roughness when measuring surface roughness out of 100 μm from the cutting edge in the direction of the rake surface, and third microscopic roughness (micro_S_{aF1}), which is microscopic surface roughness when measuring surface roughness within 100 μm from the cutting edge in the direction of the flank surface, is less than fourth microscopic roughness (micro_S_{aF2}), which is microscopic surface roughness when measuring surface roughness out of 100 μm from the cutting edge in the direction of the rake surface.

In addition, in the cutting tool according to the present invention, the first macroscopic roughness (macro_S_{aR1}) may be in a range of 0.1 μm≤macro_S_{aR1}≤0.3 μm, the first microscopic roughness (micro_S_{aR1}) may be in a range of 0.05 μm≤micro_S_{aR1}≤0.2 μm, the second macroscopic roughness (macro_S_{aR2}) may be in a range of 0.2 μm≤macro_S_{aR2}≤0.4 μm, the second microscopic roughness (micro_S_{aR2}) may be in a range of 0.1 μm≤micro_S_{aR1}≤0.25 μm, the third macroscopic roughness (macro_S_{aF1}) may be in a range of 0.15 μm≤macro_S_{aF1}≤0.35 μm, the third microscopic roughness (micro_S_{aF1}) may be in a range of 0.1 μm≤micro_S_{aR1}≤0.25 μm, and the fourth macroscopic roughness (macro_S_{aF2}) may be in a range of 0.25 μm≤macro_S_{aR2}≤0.5 μm, and the fourth microscopic roughness (micro_S_{aF2}) may be in a range of 0.15 μm≤micro_S_{aR1}≤0.35 μm.

In addition, in the cutting tool according to the present invention, the first to fourth macroscopic roughness and the first to fourth microscopic roughness may increase gradually as getting farther away from the cutting edge.

In addition, in the cutting tool according to the present invention, the hard coating film may have a composition satisfying Chemical Formula 1 below and may be provided as one or more layers.

[Chemical Formula 1] Al_{(1-a-b-c)}TiₐCr_{b}Me_{c}N (0≤a≤0.6, 0≤b≤0.5, 0≤c≤0.15, and at least one of Ti or Cr is contained, and Me is at least one of Ta, Hf, Nb, Zr, V, Y, W, Mo, Si, or B)

In addition in the cutting tool according to the present invention, a thickness of the hard coating film may be in a range of 0.02 μm to 20 μm.

### Advantageous Effects

According to the present invention, it may be possible to provide the cutting tool with the excellent adhesion to the hard coating film and the excellent welding resistance. In addition, the process efficiency may be improved in the manufacture of the cutting tool provided with the hard coating film.

### BRIEF DESCRIPTION OF THE DRAWINGS

FIG. 1 is a schematic cross-sectional view for explaining a cutting tool having a hard coating film according to the present invention.

FIG. 2 is a schematic view for explaining macroscopic roughness and microscopic roughness in the hoard coating film according to the present invention.

### MODE FOR CARRYING OUT THE INVENTION

Hereinafter, detailed descriptions related to well-known functions or configurations will be ruled out in order not to unnecessarily obscure subject matters of the present invention. Furthermore, when it is described that one includes some elements, it should be understood that it may comprise only those elements, or it may include other elements as well as those elements if there is no specific limitation.

The hard coating film cutting tool according to the present invention may include the hard base material and the hard coating film formed on the hard base material. In the hard coating film, when measuring surface roughness within a range of 100 μm from a cutting edge of the hard coating film in a direction of a rake surface, macroscopic surface roughness is referred to as first macroscopic roughness macro_S_{aR1}, when measuring surface roughness at a distance of 100 μm from the cutting edge in the direction of the rake surface, the macroscopic surface roughness is referred to as second macroscopic roughness macro_S_{aR2}, when measuring surface roughness within a range of 100 μm in the direction of the rake surface from the cutting edge, the microscopic surface roughness is referred to as first microscopic roughness micro_S_{aR1}, when measuring surface roughness at a distance of 100 μm from the cutting edge in the direction of the rake surface, the microscopic surface roughness is referred to as second microscopic roughness micro_S_{aR2}, when measuring surface roughness within a range of 100 μm from the cutting edge in the direction of the flank surface, the macroscopic surface roughness is referred to as third macroscopic roughness macro_S_{aF1}, when measuring surface roughness at a distance of 100 μm from the cutting edge in the direction of the rake surface, the macroscopic surface roughness is referred to as fourth macroscopic roughness macro_S_{aF2}, when measuring surface roughness within a range of 100 μm from the cutting edge in the direction of the flank surface, the microscopic surface roughness is referred to as third microscopic roughness micro_S_{aF1}, and when measuring surface roughness at a distance of 100 μm from the cutting edge in the direction of the rake surface, the microscopic surface roughness is referred to as fourth microscopic roughness micro_S_{aF2}, the first macroscopic roughness is less than the second macroscopic roughness, the first microscopic roughness is less than the microscopic surface roughness, the third macroscopic roughness is less than the fourth macroscopic roughness, and the third microscopic roughness is less than the fourth microscopic roughness.

The roughness of the hard coating film may be greatly affected by the roughness of the base material. When the roughness of the base material is high, bonding strength between the hard coating film and the base material increases, but there is a problem that possibility of welding with a material to be processed increases. In order to harmonize conflicting relationships in the characteristics of the hard coating film according to the roughness of the hard coating film, the hard coating film according to the present invention may have low surface roughness at a portion that is close to a center of the cutting edge to improve welding resistance and allow uniform nucleation and growth in the hard coating film, thereby relieving stress and improving chipping resistance against an intermittent impact during the cutting. In addition, the hard coating film on an area that is far from the center of the cutting edge may have higher surface roughness than that at the center of the cutting edge, thereby improving higher bonding strength of the hard coating film. When considering that peeling and tearing of the hard coating film occur intensively during the cutting, especially at a portion, which exceeds 100 μm, from the cutting edge, appropriate surface roughness is provided at the portion so that high bonding force between the base material and the hard coating film is maintained, and sufficient peeling resistance is provided.

For this, the macroscopic roughness on an area within 100 μm from the center of the cutting edge on both the rake surface and a flank surface is less than the macroscopic roughness on an area out of 100 μm from the center of the cutting edge. Similarly, the microscopic roughness on the area within 100 μm from the center of the cutting edge is less than that on the area out of 100 μm from the center of the cutting edge.

In this specification, the roughness means an arithmetic mean height as specified in ISO 25178. The roughness is generally expressed by adopting one of several parameters specified in ISO 4287 and ISO 25178. However, since only the parameters do not distinguish an overall shape change of the surface, it is easy to make errors in expressing the roughness. For example, cemented carbides are made through a process of mixing hard particles and binder powder, pressing, and liquid sintering. During the sintering, the binder is liquefied and then solidified again, the thus, roughness of irregular waves is provided on the hard base material. The hard particles having a shape of an angular polygon are fixed to the binder to protrude irregularly along the surface, thereby exhibiting fine roughness. Thus, in order to more accurately measure the surface roughness of the hard base material such as cemented carbides and cermets, it is necessary to distinguish the macroscopic roughness, which indicates roughness including changes in overall shape of the surface, and the microscopic roughness, which indicates the roughness caused by the hard particles protruding along the surface from each other. In order to measure the macroscopic roughness and the microscopic roughness separately, a micro 3D roughness measuring device and analysis software using a laser confocal and white light interferometer were used. In the present invention, Keyence's VK-X3050 equipment and its own analysis software were used. In this specification, the macroscopic roughness means an arithmetic mean height shown without any additional correction after the measurement, and the microscopic roughness means an arithmetic mean height after removing the irregular waves or large-scale components by using a correction function (L-filter) of the analysis software after the measurement. The correction means correction using a filter corresponding to a cutoff value specified in JIS B0633-2001.

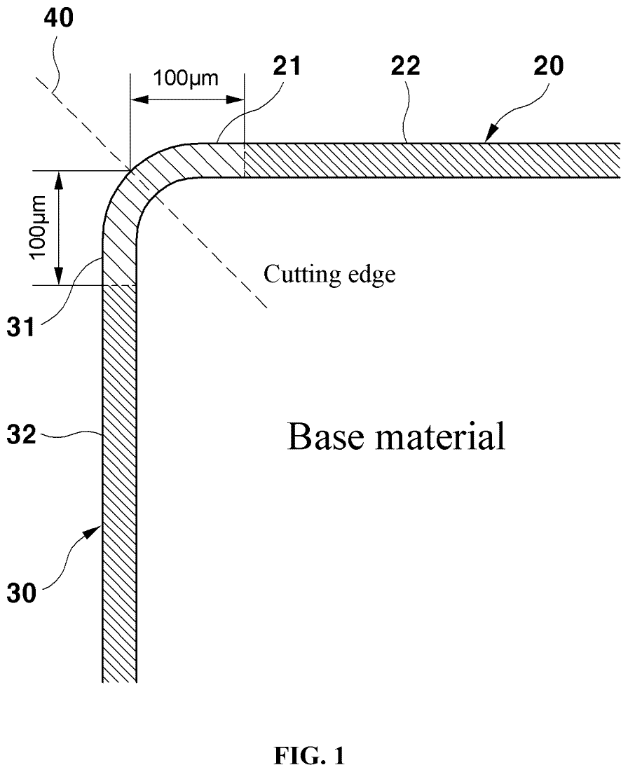

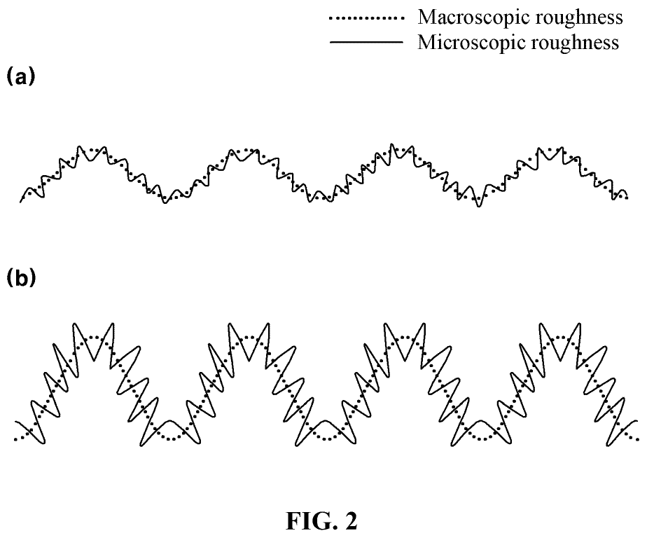

The surface roughness for each area is described with reference to FIGS. 1 and 2. The macroscopic roughness and the microscopic roughness in a range 21 within 100 μm centered on the cutting edge 40 on the rake surface 20 are less than the macroscopic roughness and the microscopic roughness in a range 22 out of 100 μm centered on the cutting edge 40. The macroscopic roughness and the microscopic roughness in a range 31 within 100 μm centered on the cutting edge 40 on the rake surface 30 are less than the macroscopic roughness and the microscopic roughness in a range 32 out of 100 μm centered on the cutting edge 40.

The macroscopic roughness and the microscopic roughness are illustrated in FIG. 2. FIG. 2(a) illustrates surface roughness in ranges 21 and 31 within 100 μm from the cutting edge 40, and FIG. 2(b) illustrates surface roughness in ranges 22 and 32 out of 100 μm from the cutting edge 40. A dotted line represents the macroscopic roughness, and a solid line represents the microscopic roughness. As illustrated in FIGS. 2(a) and 2(b), the surface roughness in the ranges 21 and 31 within 100 μm from the cutting edge 40 is less than that in both the macroscopic roughness and the microscopic roughness in the ranges 22 and 32 out of 100 μm.

In the cutting tool according to the present invention, the first macroscopic roughness macro_S_{aR1} may be in a range of 0.1 μm≤macro_S_{aR1}≤0.3 μm, the first microscopic roughness micro_S_{aR1} may be in a range of 0.05 μm≤micro_S_{aR1}≤0.2 μm, the second macroscopic roughness macro_S_{aR2} may be in a range of 0.2 μm≤macro_S_{aR2}≤0.4 μm, the second microscopic roughness micro_S_{aR2} may be in a range of 0.1 μm≤micro_S_{aR1}≤0.25 μm, the third macroscopic roughness macro_S_{aF1} may be in a range of 0.15 μm≤macro_S_{aF1}≤0.35 μm, the third microscopic roughness micro_S_{aF1} may be in a range of 0.1 μm≤micro_S_{aR1}≤0.25 μm, and the fourth macroscopic roughness macro_S_{aF2} may be in a range of 0.25 μm≤macro_S_{aR2}≤0.5 μm, and the fourth microscopic roughness micro_S_{aF2} may be in a range of 0.15 μm≤micro_S_{aR1}≤0.35≤μm.

The first to fourth macroscopic roughness and the first to fourth microscopic roughness may be compared with each other, and a certain range of the surface roughness may harmoniously maintain the adhesion, the chipping resistance, and the bonding strength of a hard coating film.

For this, the first macroscopic roughness on the lake surface may be less than the second macroscopic roughness, and also, the first macroscopic roughness may be in a range of 0.1 μm to 0.3 μm, and the second macroscopic roughness may be in a range of 0.2 μm to 0.4 μm. On the flank surface, the third macroscopic roughness may be less than the fourth macroscopic roughness, and also, the range of the third macroscopic roughness may be 0.15 μm to 0.35 μm, and the range of the fourth macroscopic roughness may be 0.25 μm to 0.5 μm.

In addition, on the lake surface, the first microscopic roughness may be less than the second microscopic roughness, and also, the first microscopic roughness may be in a range of 0.05 μm to 0.2 μm, and the second microscopic roughness may be in a range of 0.1 μm to 0.25 μm.

On the flank surface, the third microscopic roughness may be less than the fourth microscopic roughness, and also, the range of the third microscopic roughness may be in a range of 0.1 μm to 0.25 μm, and the range of the fourth microscopic roughness may be in a range of 0.15 μm to 0.35 μm.

If the macroscopic roughness is less than a certain range, the bonding strength of the hard coating film may be problematic, and if it exceeding the range, there is a problem that the adhesion and the chipping resistance are reduced. For this, the first and third macroscopic roughness need to be less than the second and fourth macroscopic roughness, respectively, and also, may be maintained within a certain range.

The reason in which the roughness range on the flank surface is greater than that on the rake surface is because slightly larger adhesion of the hard coating film on the flank surface is required. On the rake face, chip welding occurs during the process in which the processed chip is swept to be escaped, and when the chip is removed, the hard coating film is also torn off, and thus, it is important to suppress the chip welding itself as a top priority. On the flank surface, the wear and tear occur actively due to close contact with the material to be cut, and thus, the adhesion of the hard coating film is given a little more priority along with wear resistance.

In the hard coating film of the cutting tool according to the present invention, the first to fourth macroscopic roughness and the first to fourth microscopic roughness may increase gradually as getting farther away from the cutting edge.

The closer to the center of the cutting edge, the smaller the surface roughness is for adhesion and chipping resistance, and farther the center of the cutting edge, the more the surface roughness gradually increases, and thus, the bonding strength between the hard coating film and the base material may be secured.

In the cutting tool according to the present invention, the hard coating film may have a composition satisfying Chemical Formula 1 below and may be provided as one or more layers.

[Chemical Formula 1] Al_{(1-a-b-c)}TiₐCr_{b}Me_{c}N (0≤a≤0.6, 0≤b≤0.5, 0≤c≤0.15, and at least one of Ti or Cr is contained, and Me is at least one of Ta, Hf, Nb, Zr, V, Y, W, Mo, Si, or B) Nitride thin films containing Al and Ti or Cr are known to have excellent wear resistance as well as heat resistance and chipping resistance. The hard coating films may have any one metal element of Ta, Hf, Nb, Zr, V, Y, W, Mo, Si, B, in addition to Al, Ti, and Cr. The wear resistance, the chipping resistance, and the heat resistance of the hard coating film may be greatly improved through the adjustment of the metal element.

In the hard coating film, reference symbols a, b, and c may determine a composition ratio of the metal elements Al, Ti, Cr, and Me. When the composition of Al is high, wear resistance, oxidation resistance, and lubrication are better, but when the Al content is too high, there is a problem of increasing in chipping, and thus, it is preferable that the contents of Ti and Cr satisfies the following Chemical Formula: 0≤a≤0.6 and 0≤b≤0.5.

Other elements may improve the chipping resistance, the heat resistance, and the wear resistance of the hard coating film by adding Ta, Hf, etc., but if the content is high, it acts as a cause of increasing residual stress due to an increase in the amorphous phase. Therefore, it is preferable that the content of Me that is one of other element, is 0 to 0.15.

In addition, in the cutting tool according to the present invention, a thickness of the hard coating film may be in a range of 0.02 μm to 20 μm. If the thickness of the hard coating film is less than 0.02 μm, it is difficult to provide sufficient wear resistance, and if it exceeds 20 μm, the internal stress increases and thus actually increases in chipping.

### EMBODIMENTS OF THE INVENTION

Hereinafter, preferred embodiments of the present invention will be described in detail with reference to the accompanying drawings. However, the present invention is not limited to the embodiments described herein.

### Embodiment

### Manufacturing of Hard Coating Film

A polishing process was applied to a hard base material made of cemented carbide after a microblast honing process or a diamond brush honing process, and then, the hard film was formed using arc ion plating that is a physical vapor deposition (PVD) method.

In the process of polishing the hard base material, paste containing diamond particles, each of which has a size of 1 μm to 5 μm, was used, and arc targets of TiAl, AlCr, TiAlSi, and AlCrSi were used as targets for applying the hard coating film.

The hard base material was wet-microblasted and washed with ultrapure water and then mounted along a circumference at a position that is spaced a predetermined distance from a central axis on a rotary table in a dry coating state. An initial vacuum pressure in a coating chamber was reduced to 8.5×10⁵ Torr or less, a temperature was heated to 400° C. to 600° C., and a pulse bias voltage of −400 V to −200 V was applied to the rotating base material on the rotary table under an Ar gas atmosphere to perform ion bombardment for 30 minutes to 90 minutes. A gas pressure for coating was maintained at 50 mTorr or less, preferably 40 mTorr or less to form a film.

In more detail, the film was formed using TiAl, AlCr, TiAlSi, and AlCrSi targets under conditions such as a bias voltage of −100 V to −30 V, arc current of 100 A to 150 A, and a pressure of 20 mtorr to 40 mtorr by injecting N2 as a reaction gas, and the coating conditions may vary depending on equipment characteristics and conditions.

The films were manufactured under the above-described conditions according to Comparative Examples and Embodiment of the present invention, and a hard coating film having a thickness of 3.0 μm to 3.5 μm was formed using TiAl (composition ratio 50:50) and TiAlSi (composition ratio 30:60:10) targets as in Comparative Examples 1 to 2 and Embodiment 1, and a hard coating film having a thickness of 3.5 μm to 4.0 μm was formed using TiAl (composition ratio 50:50), AlCr (composition ratio 70:30), and AlCrSi (composition ratio 60:30:10) targets as in Comparative Examples 4 to 5 and Embodiment 2. Information on the macroscopic surface roughness macro_Sₐ and the microscopic surface roughness micro_Sₐ within 100 μm from the cutting edge on the corresponding rake face and the flank face is shown in Table 1 below.

TABLE 1

| | Rake surface | | | | Flank surface | | | |
|---|---|---|---|---|---|---|---|---|
| | Macroscopic | | Microscopic | | Macroscopic | | Microscopic | |
| | roughness (μm) | | roughness (μm) | | roughness (μm) | | roughness (μm) | |
| | macro_{—} | macro_{—} | micro_{—} | micro_{—} | macro_{—} | macro_{—} | micro_{—} | micro_{—} |
| Classification | S_{aR1} | S_{aR2} | S_{aR1} | S_{aR2} | S_{aF1} | S_{aF2} | S_{aF1} | S_{aF2} |
| Comparative | 0.437 | 0.483 | 0.320 | 0.304 | 0.471 | 0.459 | 0.317 | 0.322 |
| Example 1 | | | | | | | | |
| Comparative | 0.083 | 0.078 | 0.049 | 0.047 | 0.112 | 0.125 | 0.089 | 0.099 |
| Example 2 | | | | | | | | |
| Comparative | 0.454 | 0.439 | 0.346 | 0.353 | 0.520 | 0.538 | 0.368 | 0.320 |
| Example 3 | | | | | | | | |
| Comparative | 0.107 | 0.090 | 0.044 | 0.058 | 0.134 | 0.102 | 0.094 | 0.095 |
| Example 4 | | | | | | | | |
| Embodiment 1 | 0.214 | 0.289 | 0.123 | 0.188 | 0.240 | 0.379 | 0.176 | 0.226 |
| Embodiment 2 | 0.222 | 0.301 | 0.140 | 0.215 | 0.267 | 0.394 | 0.200 | 0.253 |

As shown in Table 1 above, Embodiments 1 and 2 have lower roughness overall when compared to Comparative Examples 1 and 3, and have higher roughness overall when compared to Comparative Examples 2 and 4. In addition, the roughness within 100 μm from the cutting edge has a lower value than that of the roughness out of 100 μm.

### Cutting Performance Evaluation

In order to evaluate the adhesion, the peeling resistance, and the chipping resistance of the cutting tool manufactured as shown in Table 1 above, a milling test was performed, and the evaluation was conducted under the following conditions.
1) Evaluation of welding resistance and chipping resistance
Material to be cut: GCD600
Sample Type: SNMX1206ANN-MF (Comparative Examples 1 to 2, Embodiment 1)
Cutting speed: 150 m/min
Cutting transfer: 0.2 mm/tooth
Cutting depth: 2 mm

When processing spheroidal graphite cast iron, main types of wear are generally mechanical frictional wear and tear, as well as the chipping and tearing caused by repeated adhesion and detachment of the chip. The adhesion resistance and the chipping resistance of the cutting tool have a significant impact on the cutting performance.
(2) Evaluation of peeling resistance and chipping resistance
Material to be cut: STD11
Sample Type: ADKT170608PESR-MM (Comparative Examples 3 to 4, Embodiment 2)
Cutting speed: 120 m/min
Cutting transfer: 0.2 mm/tooth
Cutting depth: 5 mm

When processing high hardness steel, excessive wear and chipping due to the tearing are generally the main types of the wear, and the peeling resistance and the chipping resistance of the cutting tool have a significant impact on the cutting performance.

TABLE 2

| | GCD600 | | STD11 | |
|---|---|---|---|---|
| | Processing results | | Processing results | |
| | Processing | | Processing | |
| | length | | length | |
| Classification | (mm) | Wear type | (mm) | Wear type |
| Comparative | 1500 | Hot crack, | — | — |
| Example 1 | | chipping | | |
| Comparative | 2700 | Thin film | — | — |
| Example 2 | | tearing, | | |
| | | excessive | | |
| | | wear | | |
| Comparative | — | — | 9000 | Excessive |
| Example 3 | | | | wear, |
| Comparative | | | 6900 | Thin film |
| Example 4 | | | | tearing, |
| | | | | chipping |
| Embodiment 1 | 4200 | Normal wear | — | — |
| Embodiment 2 | — | — | 15000 | Normal wear |

As shown in Table 2 above, the cutting tool according to Embodiments had superior cutting performance overall when compared to the cutting tool according to Comparative Examples. In the case of Comparative Examples 2 and 4, the roughness of the cutting tool was the lowest, but the adhesion between the hard base material and the hard coating film decreased to reduce the tool lifespan. Therefore, as in Embodiments, it was confirmed that the adhesion resistance, the peeling resistance, and the chipping resistance are improved by having an appropriate roughness range for each portion of the cutting tool, and that the tool lifespan is improved along with stable processing in the form of normal wear.

1. A cutting tool comprising a hard base material and a hard coating film disposed on the hard base material,
wherein, in the hard coating film, first macroscopic roughness (macro_S_{aR1}), which is macroscopic surface roughness when measuring surface roughness within a range of 100 μm from a cutting edge of the hard coating film in a direction of a rake surface, is less than second macroscopic roughness (macro_S_{aR2}), which is macroscopic surface roughness when measuring surface roughness outside of 100 μm from the edge in the direction of the rake surface, first microscopic roughness (micro_S_{aR1}), which is a microscopic surface roughness when measuring surface roughness within a range of 100 μm from the cutting edge in the direction of the rake surface, is less than second micro-roughness (micro_S_{aR2}), which is microscopic surface roughness when measuring surface roughness out of 100 μm from the cutting edge in the direction of the rake surface, third macroscopic roughness (macro_S_{aF1}), which is macroscopic surface roughness when measuring surface roughness within 100 μm from the cutting edge in the direction of the flank surface, is less than fourth macroscopic roughness (macro_S_{aF2}), which is macroscopic surface roughness when measuring surface roughness out of 100 μm from the cutting edge in the direction of the rake surface, and third microscopic roughness (micro_S_{aF1}), which is microscopic surface roughness when measuring surface roughness within 100 μm from the cutting edge in the direction of the flank surface, is less than fourth microscopic roughness (micro_S_{aF2}), which is microscopic surface roughness when measuring surface roughness out of 100 μm from the cutting edge in the direction of the rake surface.

2. The cutting tool of claim 1, wherein the first macroscopic roughness (macro_S_{aR1}) is in a range of 0.1 μm≤macro_S_{aR1}≤0.3 μm, the first microscopic roughness (micro_S_{aR1}) is in a range of 0.05 μm≤micro_S_{aR1}≤0.2 μm, the second macroscopic roughness (macro_S_{aR2}) is in a range of 0.2 μm≤macro_S_{aR2}≤0.4 μm, the second microscopic roughness (micro_S_{aR2}) is in a range of 0.1 μm≤micro_S_{aR1}≤0.25 μm, the third macroscopic roughness (macro_S_{aF1}) is in a range of 0.15 μm≤macro_S_{aF1}≤0.35 μm, the third microscopic roughness (micro_S_{aF1}) is in a range of 0.1 μm≤micro_S_{aR1}≤0.25 μm, and the fourth macroscopic roughness (macro_S_{aF2}) is in a range of 0.25 μm≤macro_S_{aR2}≤0.5 μm, and the fourth microscopic roughness (micro_S_{aF2}) is in a range of 0.15 μm≤micro_S_{aR1}≤0.35 μm.

3. The cutting tool of claim 1, wherein the first to fourth macroscopic roughness and the first to fourth microscopic roughness increase gradually as getting farther away from the cutting edge.

4. The cutting tool of claim 1, wherein the hard coating film has a composition satisfying Chemical Formula 1 below and is provided as one or more layers.
[Chemical Formula 1] Al_{(1-a-b-c)}TiₐCr_{b}Me_{c}N (0≤a≤0.6, 0≤b≤0.5, 0≤c≤0.15, and at least one of Ti or Cr is contained, and Me is at least one of Ta, Hf, Nb, Zr, V, Y, W, Mo, Si, or B)

5. The cutting tool of claim 1, wherein a thickness of the hard coating film is in a range of 0.02 μm to 20 μm.
